(19) United States
(12) Patent Application Publication
(10) Pub. No.: US 2025/0277851 A1
(43) Pub. Date: Sep. 4, 2025

(54) EXPERIMENT-IN-THE-LOOP SYSTEM FOR FAST AND EFFECTIVE TUNING OF ACTIVE VIBRATION CONTROLLERS

(71) Applicant: TECHNOLOGY INNOVATION INSTITUTE - SOLE PROPRIETORSHIP LLC, Masdar City (AE)

(72) Inventors: Tarcisio Marinelli Pereira SILVA, Abu Dhabi (AE); Prabakaran BALASUBRAMANIAN, Abu Dhabi (AE); Giulio FRANCHINI, Abu Dhabi (AE); Abdulaziz Essa BUABDULLA, Dubai (AE); Marco AMABILI, Hangzhou (CN)

(73) Assignee: TECHNOLOGY INNOVATION INSTITUTE - SOLE PROPRIETORSHIP LLC, Masdar City (AE)

(21) Appl. No.: 19/063,473

(22) Filed: Feb. 26, 2025

Related U.S. Application Data
(60) Provisional application No. 63/706,798, filed on Oct. 14, 2024.
(60) Provisional application No. 63/561,152, filed on Mar. 4, 2024.

(51) Int. Cl. G01R 31/317; G01L 5/00; G01R 31/3183; G01R 31/319

(52) U.S. Cl. CPC G01R 31/31716; G01L 5/0071; G01R 31/318307; G01R 31/318371; G01R 31/31905

(57) ABSTRACT

An experiment-in-the-loop system for determining one or more control parameters for an active controller includes a first processor and a second processor. The first processor determines one or more parameters for a first control algorithm during a series of experiments, where one or more external stimuli are applied to a device under test (DUT). The second processor derives a cost of a physical response to the one or more external stimuli based on measurements from one or more sensors. In response to an option parameter received by the second processor, a switch can select a first, second, or third controller to connect to the DUT. The first, second, or third controller produces an actuation voltage that is routed to a first stimulator device. The first stimulator device applies a first external stimulus to the DUT.

### CROSS REFERENCE TO RELATED APPLICATIONS

This application is related to U.S. Provisional Application No. 63/561,152, filed on Mar. 4, 2024 and U.S. Provisional Application No. 63/706,798, filed on Oct. 14, 2024, the disclosure of which are incorporated by reference in their entireties.

### FIELD

The present disclosure relates to systems and methods for programming an active vibration controller.

### BACKGROUND

Mechanical vibrations present significant challenges in modern structural design, especially as structures become larger and lighter. These vibrations can lead to structural damage, reduced fatigue life, and ultimately structural collapse. Effective vibration control is essential in different fields such as aerospace, automotive engineering, and civil infrastructure. Among vibration control techniques, Active Vibration Control (AVC) is often preferred due to its better performance, greater effectiveness over a wider frequency range, and reconfigurability capabilities. AVC systems employ sensors to detect vibrations, control algorithms to process the sensor data and calculate the corresponding corrective forces, and actuators to apply these forces and counteract vibrations.

One challenge in AVC techniques is the tuning of the control parameters. The proper tuning is essential to ensure that AVC systems function effectively and provide precise control. However, poorly tuning the control algorithm may lead to instability, diminished performance, and potential harm to the system. Existing solutions for reducing mechanical vibrations or optimizing outputs of a mechanical system consist of creating a numerical model of the system, numerically designing an optimal control algorithm, and testing the controller for validation. Although this approach can provide efficient control algorithms that optimize the outputs of a system, it is considerably time-consuming since the validation step may require several refinements of the numerical model of the system. Furthermore, this approach is additionally not user-friendly since it requires the knowledge of complex mathematical theories for optimizing the control algorithm and the development or refinement of the numerical model of the system.

### SUMMARY

Accordingly, what is needed is an improved method and system for autonomously generating an optimal control algorithm without the need of a numerical model of a system.

In some aspects, a system comprises a first processor and a second processor. The first processor may determine one or more parameters for a first control algorithm, during a series of experiments, where one or more external stimuli are applied to a device under test (DUT). The second processor may derive a cost of a physical response to the one or more external stimuli based on measurements from one or more sensors attached to a DUT. The second processor may also set an option parameter value that may be sent to a switch, which determines which of the first, second, or third controllers, each containing a different control algorithm, sends an actuation voltage to a saturation block. The saturation block may produce an adjusted actuation voltage that is contained within minimum and maximum bounds set by a user. A first stimulator device may receive the adjusted actuation voltage and generate a first external stimulus of the one or more external stimuli applied to the DUT.

In some aspects, a method may comprise determining final values for one or more parameters of a control algorithm and transmitting the final values to a controller. The final values for the one or more parameters of a controller may be determined through a series of iterative experiments where one or more external stimuli are applied to a device under test.

In some aspects, a non-transitory computer-readable medium may store instructions that, when executed by a processor, may cause the processor to perform operations comprising the above method.

Further features and exemplary aspects of the present disclosure, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the present disclosure and to enable those skilled in the relevant art(s) to make and use aspects herein.

FIG. 1A illustrates a block diagram of a control algorithm designed to optimize outputs of a device under test, according to some aspects.

FIG. 1B illustrates a flowchart of a linear controller, according to some aspects.

FIG. 1C illustrates a flowchart of an example architecture of a control law, according to some aspects.

FIG. 2 illustrates a flowchart of a numerical method known in the art for designing a control algorithm to optimize outputs of a device under test, according to some aspects.

FIG. 3 illustrates a block diagram of an example Experiment in the Loop (EITL) system, according to some aspects.

FIG. 4 illustrates a flowchart of an example method for designing a control algorithm from experimental tests, according to some aspects.

FIG. 5 illustrates a flowchart of an example method for generating a scalar cost value from data collected from one or more sensors, according to some aspects.

FIG. 6 illustrates a flowchart of an example method for generating a scalar cost value from data collected from one or more sensors, according to some aspects.

FIGS. 7A, 7B, 7C, 7D, and 7E illustrates experimental data collected from controllers tuned using an experiment-in-the-loop process, according to some aspects.

FIG. 8 illustrates an example computer system useful for implementing various embodiments.

In the drawings, like reference numbers generally indicate identical or similar elements. Additionally, generally, the left-most digit(s) of a reference number identifies the drawing in which the reference number first appears.

### DETAILED DESCRIPTION

Provided herein are system, apparatus, device, method and/or computer program product embodiments, and/or combinations and sub-combinations thereof, for automatically designing a controller from experimental tests, according to some aspects.

This specification discloses one or more aspects that incorporate the features of this present invention.

The aspect(s) described, and references in the specification to “one aspect,” “an aspect,” “an example aspect,” “an exemplary aspect,” etc., indicate that the aspect(s) described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to effect such feature, structure, or characteristic in connection with other aspects whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

Numerical values, including endpoints of ranges, can be expressed herein as approximations preceded by the term “about,” “substantially,” “approximately,” or the like. In such cases, other aspects include the particular numerical value. Regardless of whether a numerical value is expressed as an approximation, two aspects are included in this disclosure: one expressed as an approximation, and another not expressed as an approximation. It will be further understood that an endpoint of each range is significant both in relation to another endpoint, and independently of another endpoint.

Aspects of the disclosure may be implemented in hardware, firmware, software, or any combination thereof. Aspects of the disclosure may also be implemented as instructions stored on a machine-readable medium (e.g., memory), which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such aspects in more detail, however, it is instructive to present an example environment in which aspects of the present disclosure may be implemented.

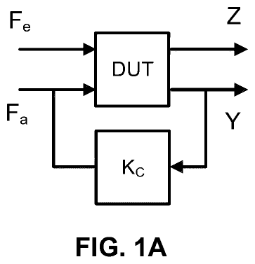

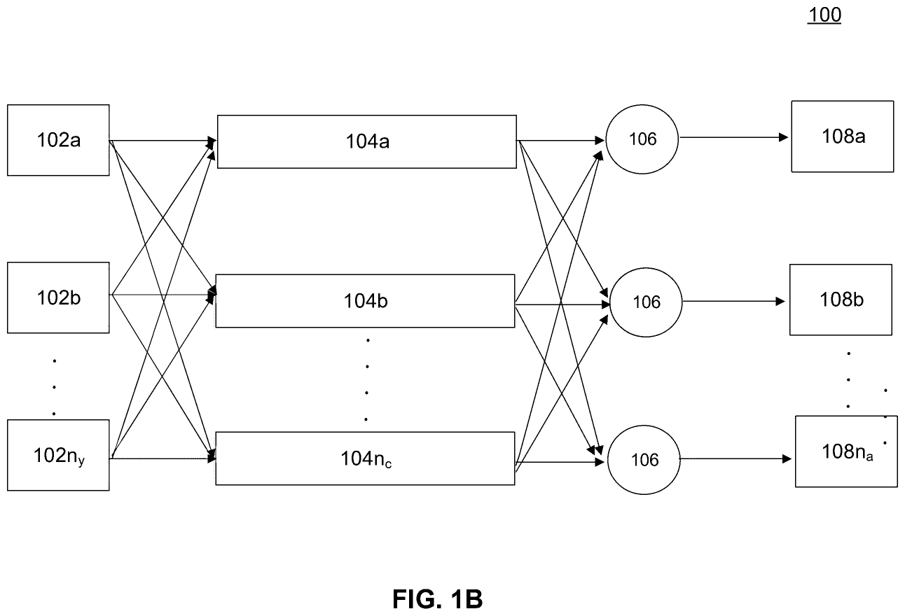

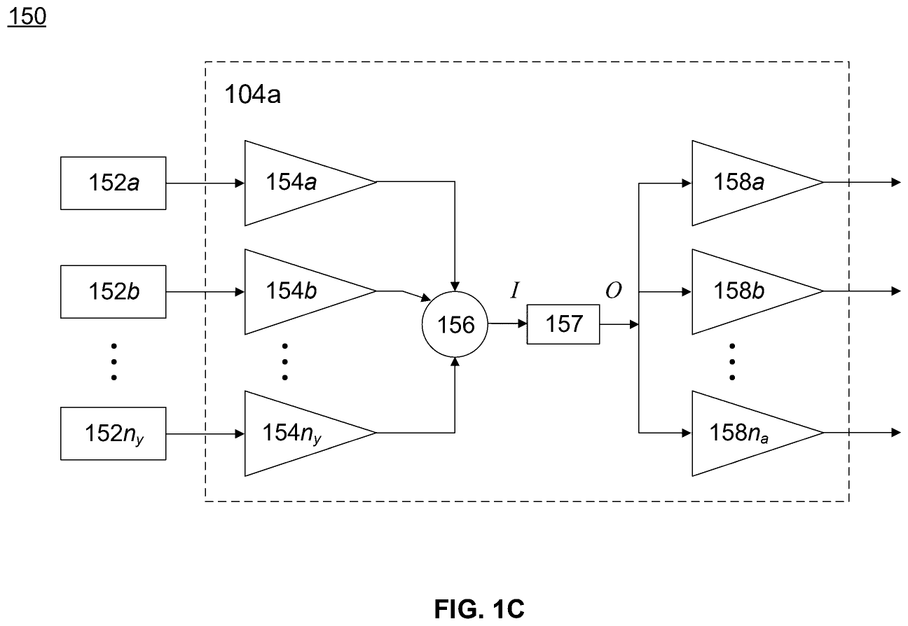

FIG. 1A illustrates a block diagram of an example controller designed to optimize outputs of a device under test (DUT), according to some aspects. The DUT may be a device (or component of a broader system) that is tested to determine performance or proficiency. The DUT may comprise, as non-limiting examples, an electronic assembly or a mechanical system, such as, a structural beam or plate, a mechanical part, an engine, or the like. In some aspects, the DUT may be subjected to external forces, Fₑ. The terms Y and Z may represent output signals from sensors coupled to the DUT, and configured to measure, as non-limiting examples, one of mechanical vibrations, acoustic sound, or temperature. A controller, K_{c}, may be configured to output actuation commands, Fₐ, based on the term Y. The actuation commands Fₐ may drive at least one stimulator device (e.g., actuator, shaker, etc.) to apply an external stimuli to the DUT. Using the resulting loop between the DUT and the controller, K_{c}, the controller may be designed in order to obtain a desired output of Y and Z.

FIG. 1B illustrates a flowchart of a linear controller 100, according to some aspects. In one example, linear controller 100 receives the sensor signals 102a, 102b, . . . 102n_{y}, (illustrated as Y in FIG. 1A) from n_{y} sensors attached to a DUT. The sensor signals may be driven to n_{c} Control laws 104a, 104b, . . . 104n_{c}. The output of each Control Law in FIG. 1B may be driven to summation blocks 106, where they are summed to generate an actuation signal vector. The actuation signal vector can be driven to nₐ actuation blocks 108a, 108b, . . . 108nₐ.

FIG. 1C illustrates a flowchart of an example architecture 150 of a single Control Law 104a shown in FIG. 1B. Other Control Law blocks (e.g., 104b . . . 104n_{c}) may have the same architecture. Control law 104a may be configured to perform a weighted sum of the sensor signals Y 152a, 152b, . . . 152n_{y} using a first set of coefficients 154a to 154n_{y} at a summation block 156. Summation block 156 may generate a first scalar output I. First scalar output I may then be multiplied by a transfer function (TF) 157, given by the mathematical expression

$$TF = \frac{{\sum }_{j = 0}^{N} {b}_{j} {s}^{j}}{{\sum }_{i = 0}^{M} {a}_{i} {s}^{i}} .$$

The coefficients a₀ to aₘ, b₀ to b_{N}, and s are Laplace's variables. Transfer function 157 may generate a second scalar output O, which may be multiplied by a second set of coefficients 158a to 158nₐ. The set of parameters composed by 152a to 152n_{y}, a₀ to aₘ, b₀ to b_{N}, and 158a to 158nₐ represent the control parameters that need to be tuned in each one of the n_{c} Control Laws.

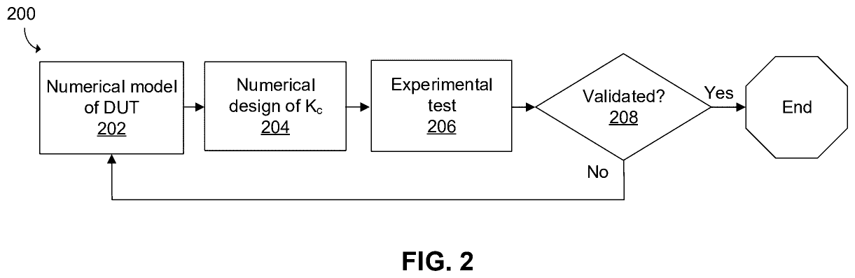

FIG. 2 illustrates a flowchart of a numerical method 200 for designing a controller (e.g., linear controller 100) to optimize outputs of a DUT, according to some aspects. At step 202 of the numerical method 200, an operator may build a numerical model of a DUT (e.g., the DUT in FIG. 1A). At step 204, the operator may perform numerical simulations to design a control algorithm (e.g., the control algorithm, K_{c}) that optimizes outputs from sensors coupled to the DUT (e.g., Y and Z). At step 206, the operator may validate the controller by performing experimental tests. At step 208, the operator may validate the experimental tests.

In some aspects, given inaccuracies in the numerical model of the DUT, the first attempt to design the controller often fails, resulting in numerical results being considerably different from experimental data. In such cases, the operator may refine the numerical model of the DUT, numerically re-design the controller, and attempt to validate the newly re-designed controller by performing experimental tests. The loop shown in FIG. 2 may be repeated until the numerical model is accurate and the controller produces desired outputs from the sensors coupled to the DUT.

In some aspects, method 200 can result in an efficient controller, but it can be considerably time consuming, where much of the time is spent conducting numerical simulations.

In some aspects, the numerical simulations may not be user-friendly as they can require the use of complex theories.

In some embodiments, an experiment-in-the-loop (EITL) process may be introduced to speed-up the tuning of a controller. In some aspects, during an EITL process an optimizer may tune a controller purely from experimental tests, by reading a system's outputs and external forces and by applying control forces to the system. In some aspects, this can exclude any need for a numerical model by applying straightforward control theory and optimization methods.

In some embodiments, the tuning of the controller may be carried out automatically, with the EITL system running hundreds or thousands of experimental tests on the system, trying different control parameters, and improving the control parameters iteratively at each test, thus converging to a solution.

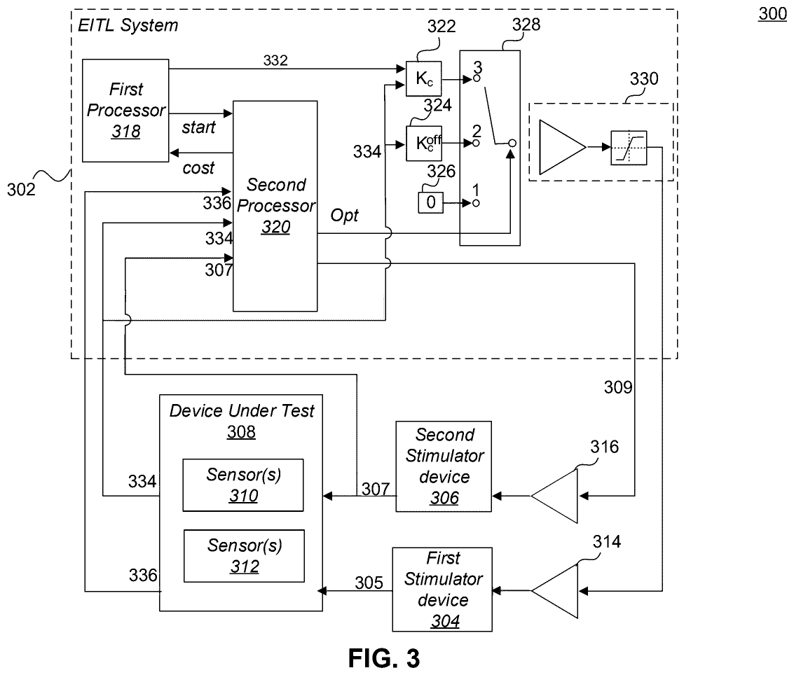

FIG. 3 illustrates a block diagram of an example environment 300, according to some aspects. For example, environment 300 can be used for automatically tuning control parameters from experimental tests, according to some aspects. The environment 300 may include an experiment-in-the-loop (EITL) system 302, a first stimulator device 304, a second stimulator device 306, a device under test (DUT) 308, first one or more sensors 310, and second one or more sensors 312. The sensor(s) 310 and the sensor(s) 312 may be coupled to the DUT 308.

In some aspects, first stimulator device 304 may apply first external stimulus 305 to the DUT 308. In the embodiment shown in FIG. 3, the first stimulator device 304 may be an actuator configured to convert an input signal, such as, an actuation voltage into an actuation force to be applied to DUT 308. In some aspects, the actuation force may be a corrective force that is applied to counteract vibrations of DUT 308. Alternatively, the actuator may convert the actuation voltage into other forms of mechanical energy (e.g., torque or displacement). The first stimulator device 304 may be coupled to a first amplifier 314, which may be configured to apply a constant gain on the actuation voltage driven to the first stimulator device 304.

In some aspects, second stimulator device 306 may apply a second external stimulus 307 to DUT 308. The second stimulator device 306 may be a shaker configured to generate an excitation force from an excitation voltage 309. In some embodiments, the excitation force may be a force that is applied to DUT 308 in order to induce vibrations of DUT 308 during experimental tests. As shown in FIG. 3, the second stimulator device 306 may be coupled to a second amplifier 316, which may be configured to apply a constant gain on the excitation voltage 309 driven to the second stimulator device 306. The second external stimuli 307 applied by the second stimulator device 306 may have the same shape and frequency content of the excitation voltage 309, but the amplitude of the second external stimuli 307 may vary over frequency and depend on the dynamic behavior of the second stimulator device 306, which is unknown.

In some aspects, DUT 308 may be a system or component that is tested to determine its performance or proficiency in response to one or more external stimuli. In the embodiment shown in FIG. 3, DUT 308 may include, without limitation, a structural beam or plate, a mechanical part, or an engine. Furthermore, in order to measure its performance or response to the one or more external stimuli, a plurality of sensors, such as first sensor(s) 310 and second sensor(s) 312, may be coupled to DUT 308.

In some aspects, the EITL system 302 may be a digital system comprising a first processor 318, a second processor 320, a first controller 322, a second controller 324, a third controller 326, a switch 328, and a saturation block 330.

In some aspects, first processor 318 may be a central processing unit (CPU), a graphics processing unit (GPU), a digital signal processor (DSP), one or more application specific integrated circuits (ASICs), or any combination of these. First processor 318 may be configured to execute an algorithm configured to determine one or more control parameters 332 of first controller 322 by minimizing a cost function input by a user. In some aspects, first processor 318 may execute a Particle Swarm Optimization algorithm. However, in other embodiments, first processor 318 may execute other algorithms such as, but not limited to, Genetic Algorithms, Artificial Bee Colony, and Ant Colony Optimization, thus enabling the use of the most suitable algorithm for a given problem.

In some aspects, first processor 318 may receive operator input specifying a DUT 308 and a cost function. A cost function may specify a performance measure to be minimized (or maximized), such as mechanical displacement or vibration of a structure, acoustic sound, temperature, harvested energy, or the like, in response to the application of one or more external stimuli to DUT 308. First processor 318 may further identify a first control algorithm K_{c} based on the selected DUT 308 and cost function.

In some aspects, first processor 318 may generate and improve the one or more control parameters 332 of the first control algorithm K_{c} during an iterative process implemented by EITL system 302. During the iterative process, first processor 318 may send a start variable to second processor 320 to initialize an experiment, wherein second processor 320 applies at least one external stimuli to DUT 308 and calculates a cost variable. The second processor 320 sends the cost variable to first processor 318. Afterwards, the first processor 318 may input the cost variable into an algorithm to determine new value(s) of the one or more parameters 332 of the first control algorithm K_{c} and transmit the new value(s) for the one or more parameters 332 to the first controller 322.

In some aspects, first processor 318 may repeatedly perform the previous obtaining, updating, transmitting steps until a terminating condition occurs. In some aspects, a terminating condition may comprise a determination that the number of experiments performed exceeds a maximum test threshold or a determination that the total cost obtained from the second processor 320 falls below a maximum cost threshold. The maximum test threshold and the maximum cost threshold may be defined by an operator or automatically configured by first processor 318.

In some aspects, second processor 320 may be a central processing unit (CPU), a graphics processing unit (GPU), a digital signal processor (DSP), one or more application specific integrated circuits (ASICs), or any combination of these. In some aspects, second processor 320 may produce an excitation voltage 309, which may be converted into second external stimulus 307 by second stimulator device 306.

In some aspects, as the second external stimulus is applied to the DUT 308, second processor 320 may collect data 334 and 336 from one or more sensors 310 and one or more sensors 312 respectively. Second processor 320 may then use the data 334 and 336 to calculate a variable cost, which is output from second processor 320 and driven to first processor 318. In some aspects, second processor 320 can output a parameter Opt, which is driven to control switch 328 and may determine which controller (e.g., 322, 324, or 326) is connected to DUT 308.

In some aspects, first controller 322 may be a programmable circuit configured to generate a first actuation voltage to drive a first stimulator device 304 to apply first external stimulus 305 to DUT 308. First controller 322 may receive, from first processor 318, one or more parameters 332 of a first control algorithm K_{c}. Furthermore, in the embodiment shown in FIG. 3, first controller 322 may also receive data 334 from one or more sensors 310 attached to DUT 308. First controller 322 may generate the first actuation voltage based on the first control algorithm K_{c}, one or more parameters 332, and data 334 from the first one or more sensors 310.

In some aspects, second controller 324 may be a fixed controller comprising a programmable circuit configured to generate a second actuation voltage using a second control algorithm K_{c}^{off}. The second control algorithm K_{c}^{off} may help to speed up experimental tests by returning DUT 308 to its equilibrium state faster than it would in an uncontrolled case where no controller is connected to DUT 308.

In some aspects, unlike the first control algorithm, the second control algorithm may be freely designed by an operator and comprise parameters with fixed, non-changing values. As shown in FIG. 3, second controller 324 may receive data 334 from the first one or more sensors 310 attached to DUT 308 and generate the second actuation voltage based on the second control algorithm K_{c}^{off} and data 334.

In some aspects, third controller 326 may be a fixed controller comprising a programmable circuit configured to generate a third actuation voltage using a third control algorithm 0. The third control algorithm may be configured to produce a null value as an actuation voltage and may be used only when an uncontrolled condition of the system is desired.

In some aspects, switch 328 may be a three-input, one-output switch configured to select one of the first, second, or third controllers. Switch 328 may be controlled by an option port configured to receive a scalar parameter Opt generated by second processor 320. In the embodiment shown in FIG. 3, parameter Opt may only assume the values 1, 2, or 3, indicating the selection of the first, second, or third controller. Based on the parameter Opt, the switch 328 may route either the first, second, or third actuation voltage to saturation block 330.

In some aspects, saturation block 330 may be a circuit configured to impose upper bounds and lower bounds on the first, second, or third actuation voltage. In some aspects, saturation block 330 may be included for safety reasons. For example, in some cases, first processor 318 may generate values for the one or more parameters of the first control algorithm that can cause first controller 322 to become unstable and produce actuation voltage levels that can damage first stimulator device 304, or DUT 308.

In some aspects, to avoid damaging any equipment, saturation block 330 may guarantee that the actuation voltage routed by switch 328 remains within acceptable limits (−Vₐ^{min}≤Vₐ≤Vₐ^{max}), which are defined by:

$${V}_{a}^{min} = max ( \frac{{F}_{a}^{min}}{{G}_{PA}} , {V}_{EITL}^{min} , {V}_{PA}^{min} )$$

and

$${V}_{a}^{min} = min ( \frac{{F}_{a}^{min}}{{G}_{PA}} , {V}_{EITL}^{max} , {V}_{PA}^{max} ) ,$$

where V_{EITL}^{min} and V_{PA}^{min} stand for the lowest voltage value that EITL 302 can output and the lowest voltage value that first amplifier 314 coupled to the first stimulator device 304 can receive, respectively.

In some aspects, the terms V_{EITL}^{max} and V_{PA}^{max} are analogous to V_{EITL}^{min} and V_{PA}^{min} for the maximum voltage values. The terms Fₐ^{min} and Fₐ^{max} are defined by the user and stands for the minimum and maximum actuation force/voltage the DUT 308 can safely withstand.

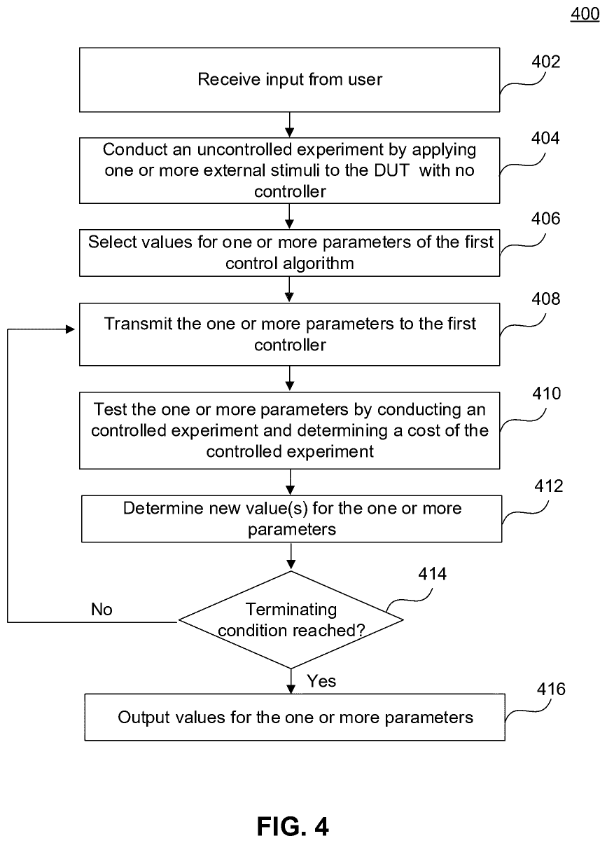

FIG. 4 illustrates a flow chart of an example method 400, according to some aspects. For example, method 400 can be used for designing a control algorithm from experimental tests, according to some aspects. Method 400 can be performed by processing logic that can comprise hardware (e.g., circuitry, dedicated logic, programmable logic, microcode, etc.), software (e.g., instructions executing on a processing device), or a combination thereof. It is to be appreciated that not all steps may be needed to perform the disclosure provided herein. Furthermore, some of the steps may be performed simultaneously, or in a different order than the one shown in FIG. 4, as will be understood by a person of ordinary skill in the art. Method 400 shall be described with reference to FIG. 3. However, method 400 is not limited to that embodiment.

At 402, EITL system 302 may receive input from a user, according to some aspects. The input may include a first control algorithm comprising one or more parameters to be tuned based on aspects (e.g., a physical response) of the DUT 308. The input may also include a cost function. In some aspects, first processor 318 may automatically identify the cost function based on the user's selection of a DUT.

At 404, EITL system 302 may conduct an uncontrolled experiment, wherein no control algorithm is implemented, according to some aspects. During the uncontrolled experiment, one or more external stimuli may be applied to DUT 308 to induce a physical response of the DUT, which may be measured by first one or more sensors 310 and/or second one or more sensors 312. Second processor 320 may receive measured data from first one or more sensors 310 and/or second one or more sensors 312 as the external stimuli are applied to DUT 308. The measured data may be used by second processor 320 to calculate a cost of the uncontrolled experiment.

At 406, EITL system 302 may select first values for the one or more parameters of a first control algorithm, according to some aspects. The first values for the one or more parameters (e.g., one or more parameters 332) may be random numbers. In some aspects, the random numbers are bound by inputs from a user.

At 408, values of the one or more parameters may be transmitted to first controller 322, according to some aspects. First controller 322 may be configured to output a first voltage, generated using a first control algorithm K_{c} and the one or more parameters 332. The first voltage may drive the first stimulator device, which may be configured to apply a first external stimulus 305 to DUT 308 during a controlled experiment.

At 410, EITL system 302 may test the one or more parameters 332 by conducting a controlled experiment, according to some aspects. During the controlled experiment, second stimulator device 306 may apply the second external stimulus 307 to DUT 308 in response to excitation voltage 309 generated by second processor 320. Second processor 320 may generate excitation voltage 309 in response to a Start variable sent by first processor 318. Second processor 320 may also set an option parameter (Opt) to 3 to indicate a controlled experiment and send this value to switch 328. In response, switch 328 may activate the first controller 322, which sends an actuation voltage to first stimulator device 304. First stimulator device 304 may then apply first external stimulus 305 to the DUT 308. First external stimulus 305 may be configured to counteract the forces generated by the second external stimulus 307.

In some aspects, the response of DUT 308 to the first external stimulus 305 and second external stimulus 307 may be measured by first one or more sensors 310 and/or second one or more sensors 312. Second processor 320 may use values from first/second one or more sensors 310 and/or 312 to evaluate a cost of the controlled experiment. In some aspects, the cost may evaluate how well the control algorithm (and associated actuation forces) mitigated external stimuli applied to the DUT.

At 412, EITL system 302 may determine new value(s) for the one or more parameters 332 of first controller 322, according to some aspects. First processor 318 may calculate new value(s) for the one or more parameters 322 using an algorithm such as: Particle Swarm Optimization, Genetic Algorithms, Artificial Bee Colony, Ant Colony Optimization, or the like. In some aspects, the algorithm is configured to minimize (or maximize) the cost function input by the user and/or determined by first processor in 402.

At 414, a terminating condition is evaluated, according to some aspects. If the terminating condition is not met, 408, 410 and 412 may be repeated. The terminating condition may be met when a maximum number of iterations (defined by the user) has been reached or when the one or more parameters achieve a desired performance.

If the terminating condition is met, final values for the one or more parameters may be output at step 416.

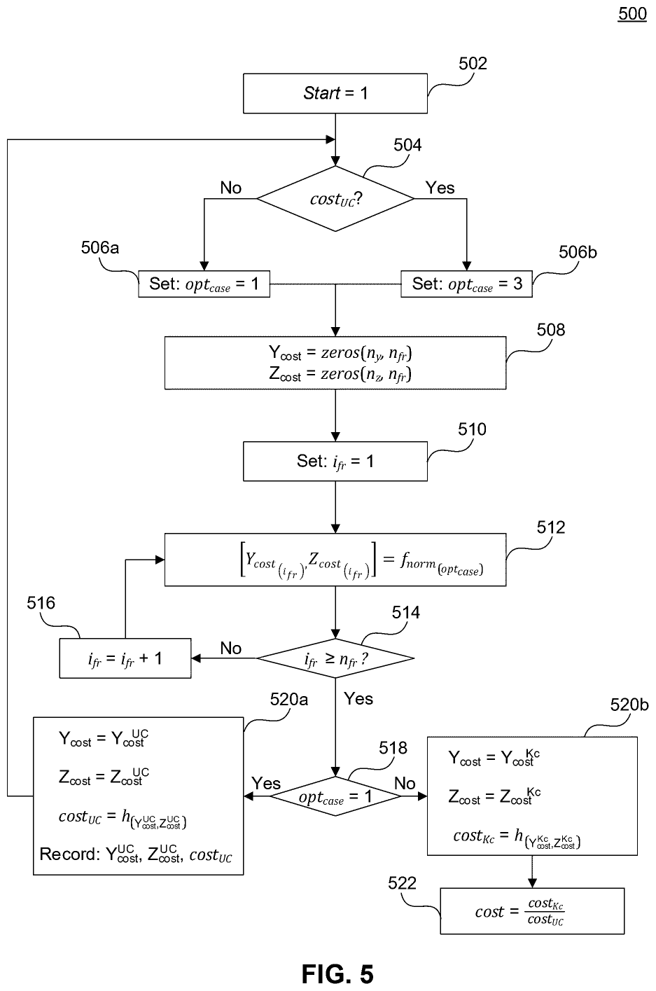

FIG. 5 illustrates a flow chart of an example method 500, according to some embodiments. For example, method 500 can be used for generating a scalar cost value of one or more external stimuli applied to a device under test, according to some aspects. Method 500 can be performed by processing logic that can comprise hardware (e.g., circuitry, dedicated logic, programmable logic, microcode, etc.), software (e.g., instructions executing on a processing device such as second processor 320), or a combination thereof. It is to be appreciated that not all steps may be needed to perform the disclosure provided herein. Furthermore, some of the steps may be performed simultaneously, or in a different order than the one shown in FIG. 5, as will be understood by a person of ordinary skill in the art.

In some aspects, method 500 may calculate the performance of a controller by minimizing a cost function. For example, method 500 may minimize the ∥H∥₂ or the ∥H∥_{∞} norm, commonly used in control theory. The ∥H∥₂ and ∥H∥_{∞} norms may be calculated from a frequency response function (FRF), which exhibits peaks at natural frequencies/resonances of a test object (e.g., DUT). For example, for a FRF containing n modes, where a total of n_{fr} (n_{fr}≤n) modes are to be controlled, a frequency range between ƒᵣᵢ and ƒ_{rf} may be defined around a resonant peak of each mode. The ∥H∥₂ norm may stand for the sum of the area underneath the FRF for each mode in the frequency range between ƒᵣᵢ and ƒ_{rf} around each resonant peak, while ∥H∥_{∞} may stand for the sum of the maximum absolute values of each resonant peak. Method 500 may be modified to carry out other minimization or maximization methods, as understood by a person of ordinary skill in the art.

Method 500 shall be described herein with reference to FIG. 3. However, method 500 is not limited to that embodiment.

At 502, method 500 may be activated, according to some aspects. Method 500 may be activated when second processor 320 receives a parameter Start=1 from first processor 318.

At 504, a parameter cost_{UC} may be probed to determine if the parameter exists in the memory of a processor, according to some aspects. The term cost_{UC} may be the cost value obtained when EITL system 302 performs an uncontrolled experiment.

If method 500 is activated for the first time, the variable cost_{UC} may not exist in the memory a processor and a scalar variable opt_{case} may be set to 1 at 506a. Otherwise, the scalar variable opt_{case} may be set to 3 at 506b.

At 508, matrices for storing determined cost values for each controlled mode (e.g., resonance modes n_{fr}), herein termed Y_{cost} and Z_{cost}, may be created and set to zero, according to some aspects. Matrices Y_{cost} and Z_{cost} may have dimensions n_{y}×n_{fr} and n_{z}×n_{fr} respectively. In some aspects, n_{fr} is the number of controlled modes of a frequency response function of DUT 308, and n_{y} and n_{z} are the number of sensors (e.g., first one or more sensors 310 and second one or more sensors 312) respectively.

At 510, a for loop may begin, according to some aspects. At the beginning of the for loop, a counter i_{fr} may be set to 1. The for loop may iteratively calculate cost values for each resonance mode of DUT 308 that is actuated by EITL system 302.

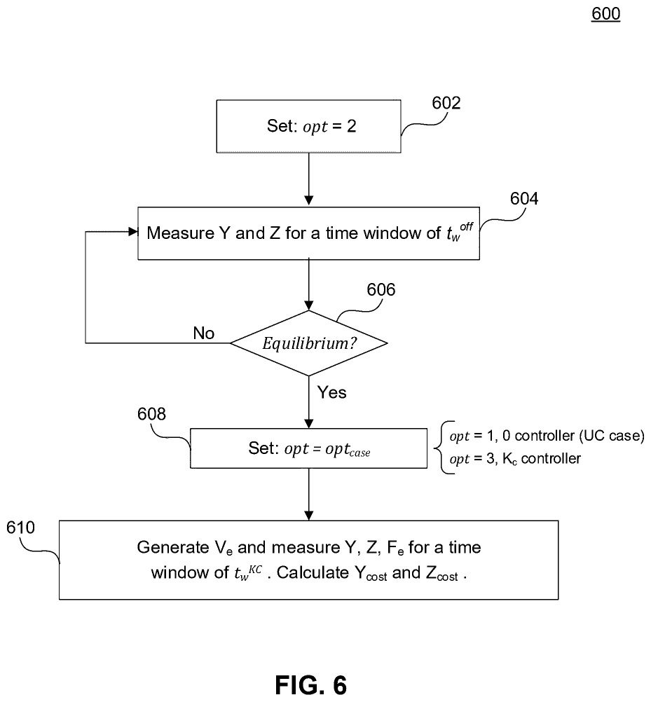

At 512, an iteration of the for loop may be executed. An iteration of the for loop may include running a function ƒₙₒᵣₘ₍ₒₚₜ_{_{case}}₎ for the i_{fr}^{th} resonance mode of DUT 308. The function ƒₙₒᵣₘ₍ₒₚₜ_{_{case}}₎ outputs Y_{cost(i}_{_{fr}}₎ and Z_{cost(i}_{_{fr}}₎, which stand for the norm ∥H∥₂ or ∥H∥_{∞} value of Y and Z, respectively. More details on ƒₙₒᵣₘ₍ₒₚₜ_{_{case}}₎ are given in FIG. 6 below.

After each iteration of the for loop, the value of i_{fr} is interrogated at 514. If i_{fr} is less than n_{fr}, the for loop continues, and a counter is applied to variable i_{fr} at 516. Iterations of the for loop are executed until i_{fr}≥n_{fr}.

Once the condition i_{fr}≥n_{fr} is met, the value of variable opt_{case} may be evaluated at 518.

If opt_{case}=1, the method may move to block 520a where the values of Y_{cost} and Z_{cost} are recorded in the functions memory under the names Y_{cost}^{UC} and Z_{cost}^{UC} respectively, according to some aspects. A scalar value cost_{UC} may also be calculated. In some aspects, cost_{UC} may be calculated using an h function, as described in appendix A. Once cost_{UC} is calculated, the flowchart may return to 504. In this case, the variable cost_{UC} exists in the processor's memory, and the scalar variable opt_{case} may be set to 3 at 506b and method 500 may evaluate the performance of controller 522 by repeating 508-514.

Once opt_{case}≠1, the method 500 may move to block 520b, where the values of the terms Y_{cost} and Z_{cost} are renamed to Y_{cost}^{Kc} and Z_{cost}^{Kc}, respectively, and may be used to calculate a scalar value cost_{Kc}. In some aspects, cost_{Kc} may be calculated using an h function, as described in appendix A.

At 522, a value of the variable cost is calculated, according to some aspects. The variable cost may be given by cost=cost_{Kc}/cost_{UC}. After calculation, the variable cost may be sent to first processor 318. After receiving the variable cost, first processor 318 may change the value of Start to zero, making second processor 320 idle. Second processor 320 may be re-initiated when the first processor sets Start equal to one.

FIG. 6 illustrates a flowchart of an example method 600, according to some aspects. For example, method 600 can be used for calculating a cost value from sensor data. Method 600 can be performed by processing logic that can comprise hardware (e.g., circuitry, dedicated logic, programmable logic, microcode, etc.), software (e.g., instructions executing on a processing device), or a combination thereof. It is to be appreciated that not all steps may be needed to perform the disclosure provided herein. Furthermore, some of the steps may be performed simultaneously, or in a different order than the one shown in FIG. 6, as will be understood by a person of ordinary skill in the art. Method 600 shall be described with reference to FIGS. 3 and 5. However, method 600 is not limited to these embodiments.

In some embodiments, method 600 may describe steps for calculating a cost value for an operating condition of the EITL system 302. For example, the steps of method 600 may be used to determine a cost of an uncontrolled experiment, or to determine a cost associated with a set of parameters applied by first controller 322. In some aspects, method 600 describes the function ƒₙₒᵣₘ₍ₒₚₜ_{_{case}}₎ as referenced in block 512 of method 500.

At 602, an equilibrium controller, such as second controller 324 may be activated, according to some aspects. Second controller 324 may be activated by sending an option parameter value of opt=2 to switch 328. As described above, second controller 324 may be configured to generate a second actuation voltage that quickly returns DUT 308 to an equilibrium state.

At 604, sensor data, herein termed Y and Z, may be measured, according to some aspects. Sensor data Y and Z may describe how DUT 308 responds with no external stimuli and may be collected from first one or more sensors 310 and second one or more sensors 312, respectively. The sensor data may be measured for a predefined time window t_{w}^{off}, which may be given by t_{w}^{off}=5/ƒₙ, where ƒₙ is a first natural frequency of the DUT 308.

At 606, the sensor data may be evaluated to determine if the DUT 308 is in an equilibrium state, according to some aspects. DUT 308 may be considered to be in the equilibrium state when sensor data terms Y and Z remain within the tolerance ranges defined by Yₜₒₗ^{min}≤Y≤Yₜₒₗ^{max}, and Zₜₒₗ^{min}≤Z≤Zₜₒₗ^{max} (defined by a user) for a time window longer than t_{w}^{off}. Since Y and Z are experimental data, they may contain noise. Therefore, the tolerance values should be slightly higher than the noise floor level of the first and second one or more sensors 310 and 312. If the system is not in equilibrium, 604 and 606 may be repeated.

At 608, a controller switch variable (i.e., opt) may be updated, according to some aspects. The controller switch variable opt may be set to opt_{case} as defined/set in 506a or 506b of method 500. When opt_{case}=1, switch 328 may be connected to controller 326, and EITL system 302 may operate in an uncontrolled condition (i.e., no actuation force is applied to DUT 308). If opt_{case}=3, switch 328 may be connected to controller 322, which determines an actuation force to be applied to DUT 308.

At 610, a perturbation voltage Vₑ may generated by the EITL system 302, according to some aspects. The voltage Vₑ may be written as a chirp or stepped sine, given by: Vₑ=chirp(ƒᵣᵢ, ƒ_{rf}, t_{w}^{Kc}) or Vₑ=stepped_sine(ƒᵣᵢ, ƒ_{rf}, t_{w}^{Kc}), where t_{w}^{Kc} is a time window during which the EITL system 302 evaluates controller 322 and ƒᵣᵢ and ƒ_{rf} are upper and lower bounds of a frequency range around a resonant peak in a frequency response function. The value of t_{w}^{Kc} may be defined by a user.

The voltage Vₑ may be driven to second amplifier 316 which amplifies the voltage before it is driven to second stimulator device 306. As described above, second stimulator device 306 may convert the voltage Vₑ to a perturbation force Fₑ, which excites DUT 308. While the perturbation force Fₑ excites DUT 308, the EITL system 302 may measure Y, Z, and Fₑ and calculate the terms Y_{cost} and Z_{cost}.

The EITL process, as described in FIGS. 3-6, may be used to determine control parameters for active controllers coupled to a variety of devices and systems. In one non-limiting example, an EITL process may be used to determine control parameters for a series of actuators attached to a composite beam.

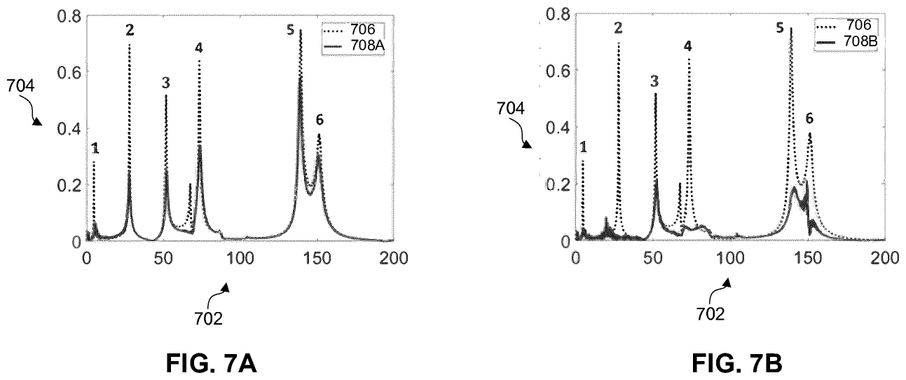

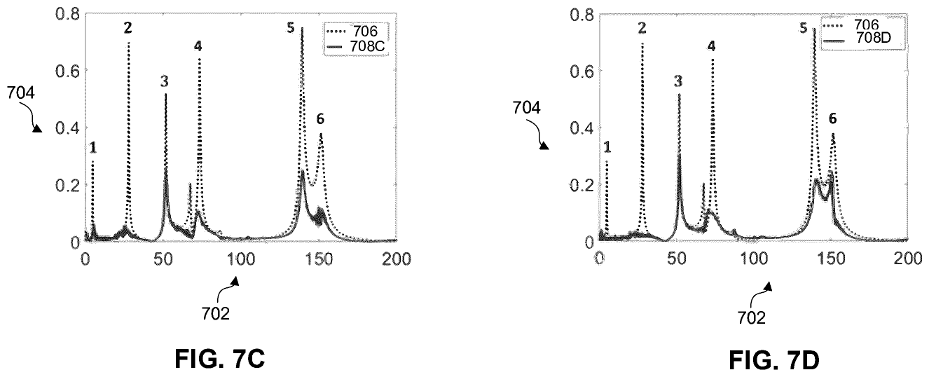

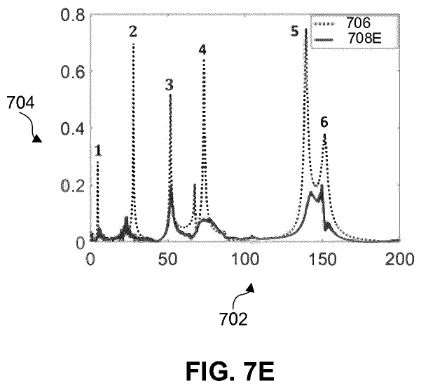

FIGS. 7A, 7B, 7C, 7D, and 7E show plots of frequency response functions of a composite beam actuated using control parameters determined experimentally using an EITL process, according to some aspects.

In this non limiting example, the data presented in FIGS. 7A-E was collected from sensors attached to a beam consisting of a 900×70×3.1 mm composite sandwich beam with a honeycomb core of 2.42 mm thickness and two external layers of carbon/epoxy in a 0/90 degrees configuration with a thickness of 0.34 mm at the top and bottom of the core. The beam was clamped at one end and free at the other end. Near the clamped end, piezoelectric patches were placed as actuators. Three additional piezoelectric patches were used as sensors.

During the EITL process, the composite sandwich beam was excited by a shaker that applied a force near the clamped end of the beam. This force was applied near one lateral edge of the beam (eccentric position), thus exciting both bending and torsional modes. The voltage output of the three piezoelectric sensors was measured using an analog circuit, and the beam's tip velocity was measured by a laser Doppler. Data collected from the piezoelectric sensors and laser Doppler were used to calculate a cost function and determine preferred control parameters.

The EITL process was repeated for five different controller configurations. Each controller configuration contained a multiple input, multiple output (MIMO) controller, which may take the form outlined in FIG. 1B. Each MIMO controller contained one or more positive position feedback (PPF) controllers. The number of PPF controllers may correspond to the number n_{c} of controllers 104 in the flowchart of FIG. 1B.

The MIMO controllers were tuned by minimizing the ∥H∥_{∞} norm in the frequency range from 0 to 200 Hz, in which the beam contained a total of four bending and two torsional modes.

FIGS. 7A, 7B, 7C, 7D, and 7E each plot a frequency response function for the composite beam using a different MIMO controller. Each plot in FIGS. 7A-7E contains an axis 702, which shows frequency in hertz (Hz), and an axis 704, which shows velocity/force in meters per second per Newton (m/s/N). Additionally, each plot in FIGS. 7A-7E contains uncontrolled frequency response data 706, collected when no controller is implemented. Normal modes (i.e., resonance modes) of the composite beam are labeled 1-6.

FIG. 7A plots controlled frequency response function data 708A, collected during the implementation of a MIMO controller containing 1 PFF. This controller contains 9 parameters that were tuned using the EITL framework.

FIG. 7B plots controlled frequency response function data 708B, collected during the implementation of a MIMO controller containing 2 PFF's. This controller contains 18 parameters that were tuned using the EITL framework.

FIG. 7C plots controlled frequency response function data 708C, collected during the implementation of a MIMO controller containing 3 PPF's. This controller contains 27 parameters that were tuned using the EITL framework.

FIG. 7D plots controlled frequency response function data 708D, collected during the implementation of a first version (V1) of a MIMO controller containing 6 PPF's. This controller contains 54 parameters that were tuned using the EITL framework.

FIG. 7E plots controlled frequency response function data 708E, collected during the implementation of a second version (V2) of a MIMO controller containing 6 PPF's. This controller contains 54 parameters that were tuned using the EITL framework.

Each MIMO controller reduced the vibrations of all six normal modes. In general, stronger vibrational reduction for all the six modes was achieved when at least 2 PPF's were employed in the MIMO controller. Further, increase in the number of implemented PPF's did not necessarily provide a better control. The vibration reduction obtained using a controller with 2 PPFs is similar to the performance of the 3 PPFs, 6 PPFs V1, and 6 PPFs V2 cases.

The controllers with 6 PPFs V1 and 6 PPFs V2 stand for two consecutive runs of the EITL system given the same inputs. This shows that an EITL system may lead to different solutions every time it runs, even when the inputs are not modified. Both the 6 PPFs V1 and 6 PPFs V2 cases present strong vibration control, as seen in FIGS. 7D and 7E. However, the 6 PPFs V1 case reduces the two first peaks more aggressively at the expense of reducing less of the higher modes, whereas the 6 PPFs V2 case provides a more homogeneous reduction on all modes.

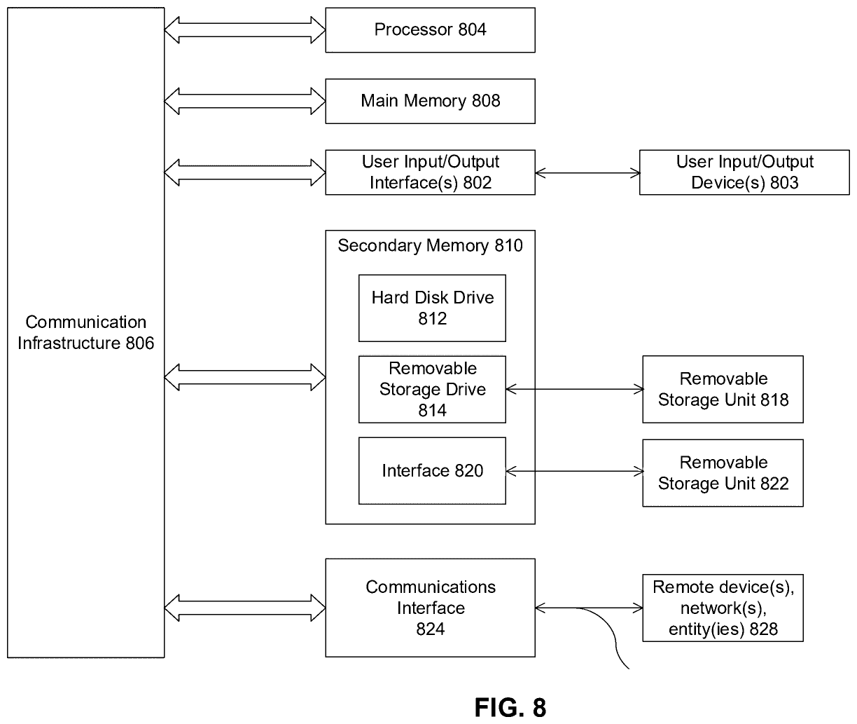

FIG. 8 illustrates an example computer system 800 useful for implementing various embodiments in FIGS. 3-7.

Computer system 800 may include one or more processors (also called central processing units, or CPUs), such as a processor 804. Processor 804 may be connected to a communication infrastructure or bus 806.

Computer system 800 may also include user input/output device(s) 803, such as monitors, keyboards, pointing devices, etc., which may communicate with communication infrastructure 806 through user input/output interface(s) 802.

One or more of processors 804 may be a graphics processing unit (GPU). In an embodiment, a GPU may be a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computer system 800 may also include a main or primary memory 808, such as random access memory (RAM). Main memory 808 may include one or more levels of cache. Main memory 808 may have stored therein control logic (i.e., computer software) and/or data.

Computer system 800 may also include one or more secondary storage devices or memory 810. Secondary memory 810 may include, for example, a hard disk drive 812 and/or a removable storage device or drive 814. Removable storage drive 814 may be a floppy disk drive, a magnetic tape drive, a compact disk drive, an optical storage device, tape backup device, and/or any other storage device/drive.

Removable storage drive 814 may interact with a removable storage unit 818. Removable storage unit 818 may include a computer usable or readable storage device having stored thereon computer software (control logic) and/or data. Removable storage unit 818 may be a floppy disk, magnetic tape, compact disk, DVD, optical storage disk, and/any other computer data storage device. Removable storage drive 814 may read from and/or write to removable storage unit 818.

Secondary memory 810 may include other means, devices, components, instrumentalities or other approaches for allowing computer programs and/or other instructions and/or data to be accessed by computer system 800. Such means, devices, components, instrumentalities or other approaches may include, for example, a removable storage unit 822 and an interface 820. Examples of the removable storage unit 822 and the interface 820 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computer system 800 may further include a communication or network interface 824. Communication interface 824 may enable computer system 800 to communicate and interact with any combination of external devices, external networks, external entities, etc. (individually and collectively referenced by reference number 828). For example, communication interface 824 may allow computer system 800 to communicate with external or remote devices 828 over communications path 826, which may be wired and/or wireless (or a combination thereof), and which may include any combination of LANs, WANs, the Internet, etc. Control logic and/or data may be transmitted to and from computer system 800 via communication path 826.

Computer system 800 may also be any of a personal digital assistant (PDA), desktop workstation, laptop or notebook computer, netbook, tablet, smart phone, smart watch or other wearable, appliance, part of the Internet-of-Things, and/or embedded system, to name a few non-limiting examples, or any combination thereof.

Computer system 800 may be a client or server, accessing or hosting any applications and/or data through any delivery paradigm, including but not limited to remote or distributed cloud computing solutions; local or on-premises software (“on-premise” cloud-based solutions); “as a service” models (e.g., content as a service (CaaS), digital content as a service (DCaaS), software as a service (SaaS), managed software as a service (MSaaS), platform as a service (PaaS), desktop as a service (DaaS), framework as a service (FaaS), backend as a service (BaaS), mobile backend as a service (MBaaS), infrastructure as a service (IaaS), etc.); and/or a hybrid model including any combination of the foregoing examples or other services or delivery paradigms.

Any applicable data structures, file formats, and schemas in computer system 800 may be derived from standards including but not limited to JavaScript Object Notation (JSON), Extensible Markup Language (XML), Yet Another Markup Language (YAML), Extensible Hypertext Markup Language (XHTML), Wireless Markup Language (WML), MessagePack, XML User Interface Language (XUL), or any other functionally similar representations alone or in combination. Alternatively, proprietary data structures, formats or schemas may be used, either exclusively or in combination with known or open standards.

In some embodiments, a tangible, non-transitory apparatus or article of manufacture comprising a tangible, non-transitory computer useable or readable medium having control logic (software) stored thereon may also be referred to herein as a computer program product or program storage device. This includes, but is not limited to, computer system 800, main memory 808, secondary memory 810, and removable storage units 818 and 822, as well as tangible articles of manufacture embodying any combination of the foregoing. Such control logic, when executed by one or more data processing devices (such as computer system 800), may cause such data processing devices to operate as described herein.

Based on the teachings contained in this disclosure, it will be apparent to persons skilled in the relevant art(s) how to make and use embodiments of this disclosure using data processing devices, computer systems and/or computer architectures other than that shown in FIG. 8. In particular, embodiments can operate with software, hardware, and/or operating system implementations other than those described herein.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

### Appendix A

### Calculating Cost Using the h Function

In some non-limiting embodiments and examples, the h function may be used to calculate the dimensionless scalar parameter cost (e.g., cost_{UC} or cost_{Kc}) based on the values of Y_{cost} and Z_{cost}. To this end, the first step is to calculate the dimensionless cost terms Y_{cost}^{adm} and Z_{cost}^{adm}, such as, Y_{cost(i,k)}^{adm}=Y_{cost(i,k)}^{input}/Y_{cost(i,k)}^{UC} and Z_{cost(j,k)}^{adm}=Z_{cost(j,k)}^{input}/Z_{cost(j,k)}^{UC}, for i=1, 2, . . . , n_{y}, j=1, 2, . . . , n_{z}, and k=1, 2, . . . , n_{fr}, where Y_{cot}^{input} and Z_{cost}^{input} are the inputs of h function.

In some aspects, each element of the dimensionless cost terms Y_{cost}^{adm} and Z_{cost}^{adm} can be equal to one in the uncontrolled condition, lower than one if the i_{fr}^{th} mode is attenuated, and higher than one if the mode is excited. The normalization of Y_{cost}^{adm} and Z_{cost}^{adm} can remove the physical unit (such as volts, current, force, etc.) associated with Y and Z, thus allowing comparison of their cost values.

In some aspects, the size of Y_{cost}^{adm} and Z_{cost}^{adm} is n_{y}×n_{fr} and n_{z}×n_{fr}, respectively. The dependency with n_{y}, n_{z}, and n_{fr} is eliminated by adding all elements of Y_{cost}^{adm} and Z_{cost}^{adm}, such that, Yₜₒₜₐₗ=Σᵢ₌₁^{ny}(Σⱼ₌₁^{nfr}wₘ₍ⱼ₎Y_{cost}^{adm}_{(i,j)}) and Zₜₒₜₐₗ=Σᵢ₌₁^{nz}(Σⱼ₌₁^{nfr}wₘ₍ⱼ₎Z_{cost}^{adm}_{(i,j)}). Here , n_{y} is the number of first sensors, n_{z} is the number of second sensors, and n_{fr} is the number of modes to be tuned, and wₘ is a weighting coefficient vector defined by a user whose dimension is 1×n_{fr}. The weighting coefficient vector allows the weight of each mode to be considered. in the optimization.

In some aspects, the terms Yₜₒₜₐₗ and Zₜₒₜₐₗ are scalar, and they compose the variable cost (output of the h function) given by: cost=Yₜₒₜₐₗ+Zₜₒₜₐₗ.

What is claimed is:

1. A system, comprising:
a first processor configured to:
determine, during each experiment in a series of experiments applying one or more external stimuli to the DUT, one or more parameters for a first control algorithm; and
a second processor configured to:
derive a cost of a physical response based on measurements from one or more sensors attached to the DUT and configured to measure a physical response to the one or more external stimuli applied to the DUT; and
set an option parameter value;
a first controller configured to produce a first actuation voltage based on a first control algorithm;
a second controller configured to produce a second actuation voltage based on a second control algorithm;
a third controller configured to produce a third actuation voltage comprising a null value;
a switch configured to:
select, based on the option parameter value obtained from the second processor, one of the first, second, and third controllers to connect to the DUT;
route, based on the which of the first, second, or third controller is selected, the first, second, or third actuation voltage;
a saturation block configured to produce an adjusted actuation voltage from the first, second, or third actuation voltage that ensures that the first, second, or third actuation voltage is within a minimum voltage threshold and a maximum voltage threshold; and
a first stimulator device configured to generate a first external stimulus of the one or more external stimuli applied to the DUT based on the adjusted actuation voltage. a second stimulator device configured to generate a second external stimulus of the one or more external stimuli applied to the DUT based on a perturbation voltage.

2. The system of claim 1, wherein:
the first stimulator device comprises at least one actuator device; and
the first external stimulus comprises an actuation force generated by the at least one actuator device.

3. The system of claim 1, wherein the second processor is further configured to:
receive an intensity value for a second external stimulus of the one or more external stimuli applied to the DUT; and
output the perturbation voltage.

4. The system of claim 1, wherein:
the second stimulator device comprises at least one shaker device, and
the second external stimulus comprises a mechanical force generated by the at least one shaker device.

5. The system of claim 1, wherein the second control algorithm returns the DUT to an equilibrium state.

6. The system of claim 1, wherein the first controller is further configured to:
obtain the one or more parameters from the first processor;
receive measurements from at least one sensor in the one or more sensors.

7. The system of claim 1, wherein the second controller is further configured to:
receive measurements from at least one sensor in the one or more sensors.

8. The system of claim 1, wherein the first processor is further configured to determine the one or more parameters by:
minimizing the cost obtained from the second processor.

9. The system of claim 8, wherein the first processor is further configured to minimize the cost obtained from the second processor using a particle swarm algorithm, Genetic Algorithms, Artificial Bee Colony, or Ant Colony Optimization.

10. A method, comprising:
determining, through a series of iterative experiments, final values for one or more parameters for a control algorithm, wherein one or more external stimuli are applied to a device under test (DUT) during the series of iterative experiments; and
transmitting the final values of the one or more parameters to a controller.

11. The method of claim 10, wherein determining further comprises:
conducting an uncontrolled experiment by applying the one or more external stimuli to the DUT with no controller;
receiving, by the first processor, a cost for the uncontrolled experiment derived by a second processor; and
selecting, by the first processor, random numbers for first values of the one or more parameters in the first control algorithm.

12. The method of claim 10, wherein the determining further comprises
transmitting, by the first processor, the first values of the one or more parameters to the controller, wherein the controller is configured to output a first voltage, generated using the control algorithm and the first values for the one or more parameters, to drive a first stimulator device configured to apply a first external stimulus to the DUT during a controlled experiment; and
obtaining, by the first processor, a cost for the controlled experiment derived by the second processor.

13. The method of claim 12, further comprising:
updating, by the first processor, the one or more parameters by determining, based on a cost function and the cost for the controlled experiment, a new value for at least one parameter of the one or more parameters;
sending, by the first processor and after the updating, the new value for the at least one parameter of the one or more parameters to the controller, wherein the controller is further configured to output a first voltage, generated using the control algorithm and the new value for the at least one parameter of the one or more parameters, to drive a first stimulator device configured to apply a first external stimulus in the one or more external stimuli to the DUT during a subsequent controlled experiment; and
obtaining, by the first processor, a cost for the subsequent controlled experiment derived by the second processor.

14. The method of claim 13, further comprising:
repeatedly performing the updating, the sending, and the obtaining until a terminating condition occurs,
wherein the terminating condition comprises one of determining that a number of subsequent controlled experiments conducted equals a maximum test threshold or determining that the cost of the subsequent controlled experiment falls below a maximum cost threshold.

15. The method of claim 13, wherein obtaining the cost for the uncontrolled experiment, the cost for the controlled experiment, and the cost for the subsequent controlled experiment comprises:
determining, by the second processor, a first cost of a physical response based on measurements from a first one or more sensors attached to the DUT;
determining, by the second processor, a second cost of a physical response based on measurements from a second one or more sensors attached to the DUT; and
aggregating, by the second processor, the first cost and the second cost.

16. The method of claim 10, wherein the determining further comprises applying by a second stimulator device, a second external stimulus of the one or more external stimuli applied to the DUT, wherein the second stimulator device is driven by a second voltage obtained from the second processor.

17. A non-transitory computer-readable medium storing instructions that, when executed by a processor, cause the processor to perform operations comprising:
determining, through a series of iterative experiments, a final set of one or more parameters for a first control algorithm, wherein one or more external stimuli are applied to a device under test (DUT) during the series of iterative experiments; and
transmitting the final set of one or more parameters to a first controller.

18. The non-transitory computer-readable medium of claim 17, the determining further comprising:
conducting an uncontrolled experiment by applying the one or more external stimuli to the DUT with no controller;
receiving, by the first processor, a cost for the uncontrolled experiment derived by a second processor;
selecting, by the first processor, random numbers for first values of the one or more parameters in the first control algorithm;
transmitting, by the first processor, the first values of the one or more parameters to the controller, wherein the controller is configured to output a first voltage, generated using the control algorithm and the first values for the one or more parameters, to drive a first stimulator device configured to apply a first external stimulus to the DUT during a controlled experiment; and
obtaining, by the first processor, a cost for the controlled experiment derived by the second processor.

19. The non-transitory computer-readable medium of claim 18, the determining further comprising:
updating, by the first processor, the one or more parameters by determining, based on a cost function and the cost for the controlled experiment, a new value for at least one parameter of the one or more parameters;
sending, by the first processor and after the updating, the new value for the at least one parameter of the one or more parameters to the controller, wherein the controller is further configured to output a first voltage, generated using the control algorithm and the new value for the at least one parameter of the one or more parameters, to drive a first stimulator device configured to apply a first external stimulus in the one or more external stimuli to the DUT during a subsequent controlled experiment; and
obtaining, by the first processor, a cost for the subsequent controlled experiment derived by the second processor.

20. The non-transitory computer-readable medium of claim 19, the determining further comprising:
repeatedly performing the updating, the sending, and the obtaining until a terminating condition occurs,
wherein the terminating condition comprises one of determining that a number of subsequent controlled experiments conducted equals a maximum test threshold or determining that the cost of the subsequent controlled experiment falls below a maximum cost threshold.
